(19) United States
(12) Patent Application Publication
(10) Pub. No.: US 2014/0029211 A1
(43) Pub. Date: Jan. 30, 2014

(54) CHIP CARD HOLDER WITH PROTECTIVE COVER FOR PORTABLE ELECTRONIC DEVICES

(71) Applicants: SHENZHEN FUTAIHONG PRECISION INDUSTRY CO., LTD., Shenzhen (CN); FIH (HONG KONG) LIMITED, Kowloon (HK)

(72) Inventor: YAN-LING GAO, Shenzhen (CN)

(73) Assignees: FIH (Hong Kong) Limited, Kowloon (HK); SHENZHEN FUTAIHONG PRECISION INDUSTRY CO., LTD., Shenzhen (CN)

(21) Appl. No.: 13/863,910

(22) Filed: Apr. 16, 2013

(30) Foreign Application Priority Data
Jul. 24, 2012 (CN) 201210257351.1

(51) Int. Cl. H05K 5/00

(52) U.S. Cl. CPC H05K 5/0091
USPC 361/747

(57) ABSTRACT

A chip card holder includes a housing, a receiving frame, an ejecting member, a tray, a protective cover, and two sliders. The housing defines a through hole and two latching grooves. The receiving frame is mounted on the housing. The ejecting member is positioned at one end of the receiving frame. The tray is slidably received in the receiving frame and abutted by the ejecting member. The protective cover is mounted to the tray and received in the through hole. The two sliders are slidably positioned on the protective cover and releasbly received in the latching grooves. When the two sliders slide relative to the protective cover and are unlocked from the housing, the ejecting member ejects the tray from the housing.

### BACKGROUND

1. Technical Field

The present disclosure relates to chip card holders, and particularly to a chip card holder with a protective cover for portable electronic devices.

2. Description of Related Art

With the development of wireless communication and information processing technologies, portable electronic devices such as mobile phones are now widely used. Surface contact cards are necessary elements in portable electronic devices.

Many chip card holders include a protective cover, which is directly exposed from housings of the portable electronic device. The exposed cover defines a hole for convenient insertion and removal of the surface contact card with a tool. However, the hole in the portable electronic device affects the appearance. In addition, the tool is easily lost, and the operation of removing the protective cover is troublesome.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the exemplary chip card holder and portable electronic device using the chip card holders. Moreover, in the drawings like reference numerals designate corresponding parts throughout the several views. Wherever possible, the same reference numbers are used throughout the drawings to refer to the same or like elements of an embodiment.

FIG. 1 is an exploded view of one embodiment of a chip card holder used in a portable electronic device.

FIG. 2 is an assembled view of the chip card holder, showing a protective cover in a closed state.

FIG. 3 is similar to FIG. 2, but viewed from another aspect.

FIG. 4 is a schematic view of the chip card holder of FIG. 3, showing the protective cover in an unlocked state.

FIG. 5 is similar to FIG. 4, but viewed from anther aspect.

FIG. 6 is similar to FIG. 4, but showing the protective cover extending out of the housing.

### DETAILED DESCRIPTION

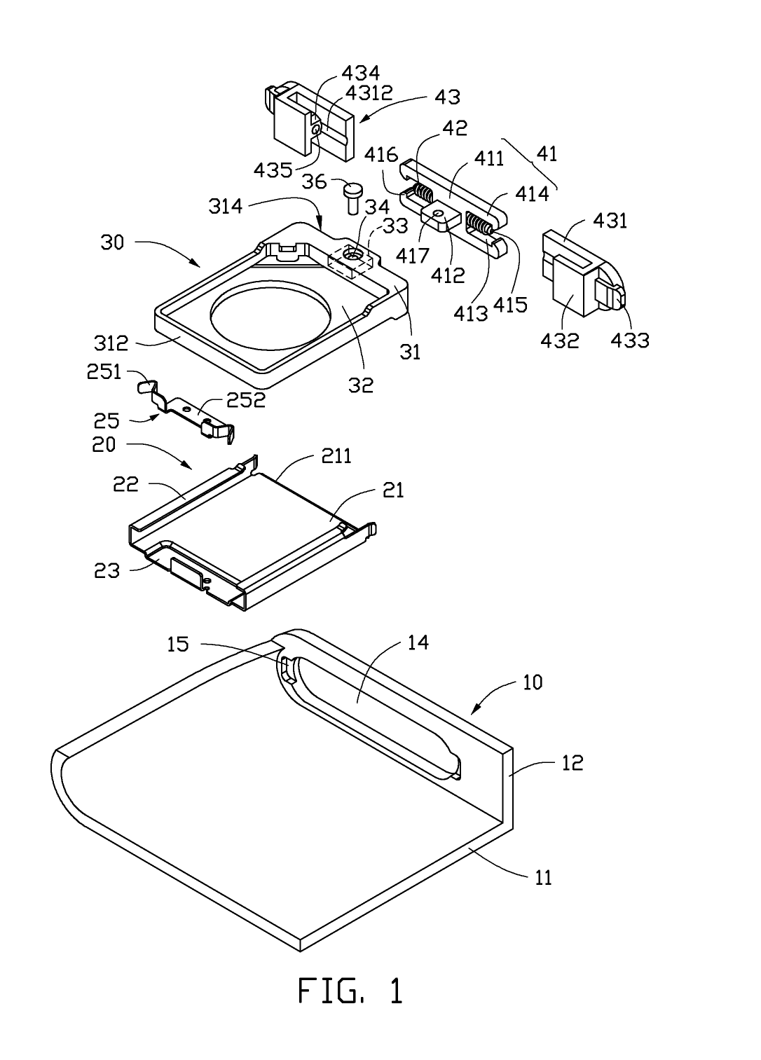

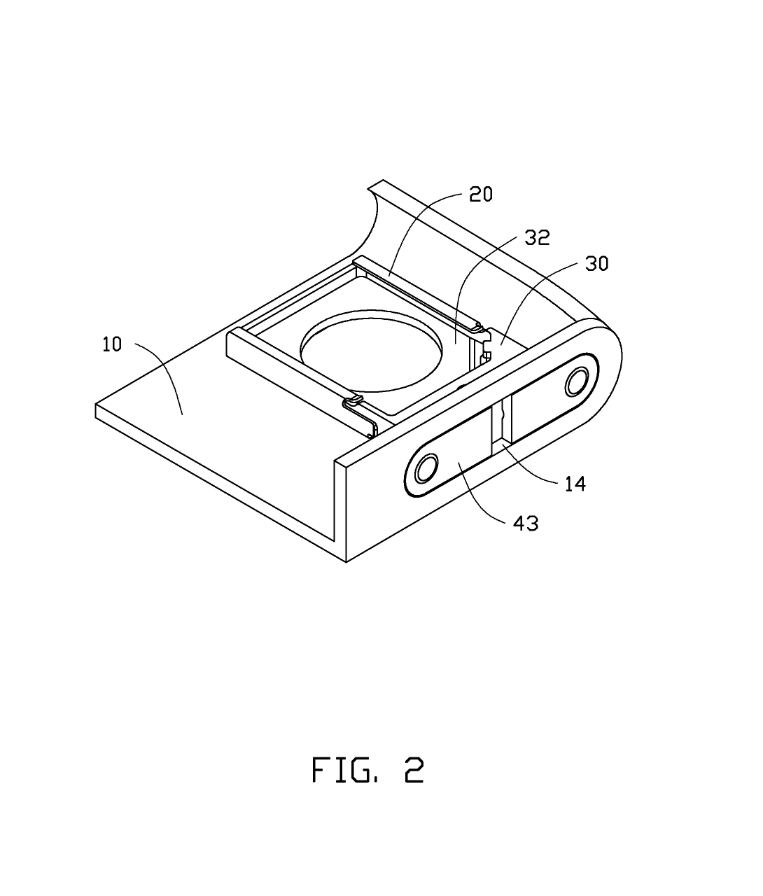

Referring to FIGS. 1 to 3, shown is an exemplary embodiment of a chip card holder which can be used in a portable electronic device, such as a cellular phone or any electronic device where a chip card is required. The portable electronic device includes a housing 10. The chip card holder is assembled in the housing 10. A chip card (not shown) can be selectively placed in the chip card holder. The chip card may be a subscriber identity module (SIM) card or a flash card.

The chip card holder includes a receiving frame 20, an ejecting member 25, a tray 30, a cover 41, two elastic members 42, and two sliders 43.

The housing 10 may be a portion of the portable electronic device or a separate element fixed to the portable electronic device. In this exemplary embodiment, the housing 10 is a top portion or a bottom portion of the portable electronic device. The housing 10 includes a main body 11 and an end wall 12 integrated with the main body 11. The end wall 12 defines a through hole 14. Opposite ends of the hole 14 respectively define a latching groove 15. The chip card holder can be received inside of the housing 10 through the hole 14, and is supported by the main body 11.

The receiving frame 20 is secured on the housing 10 adjacent to the hole 14. The receiving frame 20 includes a frame body 21 and two opposite flanges 22, thereby cooperatively defining a receiving cavity communicating with the hole 14 for receiving the tray 30. An entrance 211 is defined at a first end of the frame body 21 to allow the tray 30 to be inserted into the receiving cavity therethrough. A recessed portion 23 is formed at a second end of the frame body 21.

The ejecting member 25 is mounted on the recessed portion 23 of the receiving frame 20 and configured for abutting against the tray 30. In this exemplary embodiment, the ejecting member 25 is made of an elastic sheet, and includes two V-shaped elastic bodies 251 and a mounting portion 252. The two V-shaped elastic bodies 251 can provide an elastic force for ejecting the tray 30 from the receiving frame 20. The mounting portion 252 is located between the V-shaped elastic bodies 251, and is used to mount the ejecting member 25 on the recessed portion 23 of the frame body 21.

The tray 30 includes a tray body 31 configured for being slidably received in the receiving frame 20. The tray body 31 defines a receiving groove 32 in one surface for receiving the chip card. The tray body 31 includes a first end 312 and a second end 314. The first end 312 is configured for abutting against the V-shaped elastic bodies 251. The second end 314 defines a slot 33 and a receiving hole 34 communicating with each other.

The protective cover 41 is configured for slidably engaged in the hole 14. The protective cover 41 is substantially H-shaped, and includes a cover body 411 and two pairs of opposite arms 414 integrated with the cover body 411. An extending block 412 perpendicularly extends from the body 411. A pin hole 417 is defined in the extending block 412. A space 413 is defined between the two opposite arms 414 of each pair. A post 415 projects from each of two ends of the cover body 411, and is positioned between one pair of arms 414. A distal end of each arm 414 has a hook 416 projecting into the space 413. In this exemplary embodiment, the elastic member 42 is a helical compression spring. The elastic member 42 is configured for being received in the space 413, and is fitted around the post 415. When the extending block 412 is received in the slot 33 of the tray 30, the receiving hole 34 is aligned with the pin hole 417. A pin 36 can be engaged in the receiving hole 34 and the pin hole 417 such as through friction fit or threaded engagement.

Each slider 43 includes a first plate 431, a second plate 432, a connecting block 434, and a latching plate 433 integrally formed together. The second plate 432 is substantially configured in an L-shape, and extends from the first plate 431. The second plate 432 includes a first portion perpendicularly extending from the first plate 431, and a second portion parallel to the first plate 431. The second portion of the second plate 432 is shorter than the first plate 431. A guiding groove 4312 is defined in the first plate 431 configured for guiding a corresponding elastic member 42. The connecting block 434 is positioned between the first plate 431 and the second plate 432. A guiding hole 435 is defined in the connecting block 434. The latching plate 433 is positioned at one end of the first plate 431, and is connected to the first portion of the second plate 431. The latching plate 433 is configured for being received in the latching groove 15. The protective cover 41 is configured for slidably engaging with one of the sliders 43. In this exemplary embodiment, the two opposite arms 414 of each pair of the protective cover 41 are engaged with one end of the connecting block 434 of each slider 43, and one post 415 between the two opposite arms 414 is slidably received in the guiding hole 435. One end of each elastic member 42 is fitted around the post 415, and another end of each elastic member 42 abuts against one end of the connecting block 434.

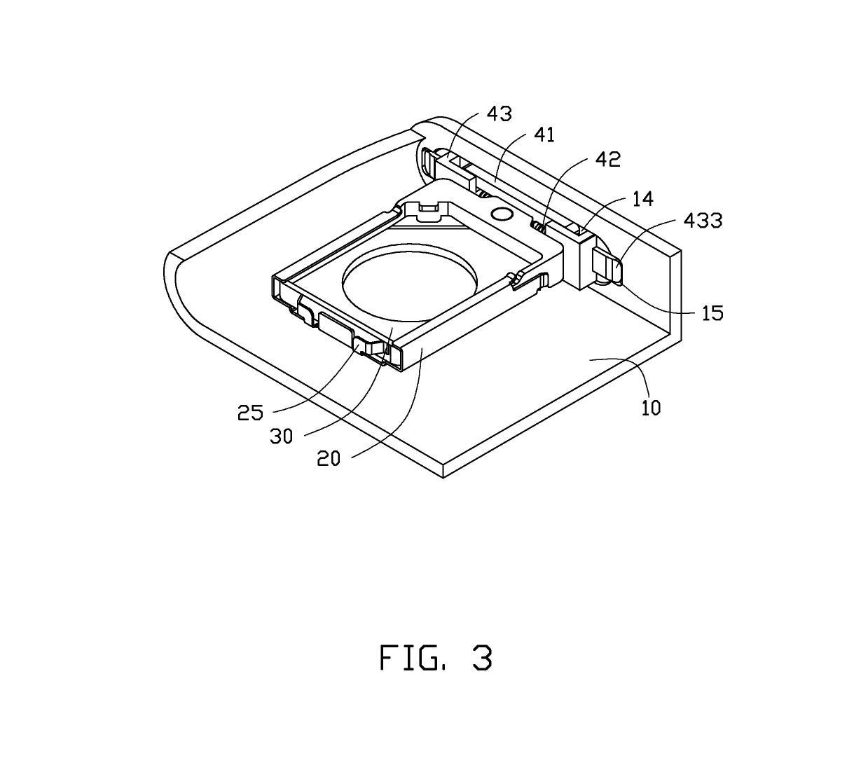

During assembly, referring to FIG. 3, the mounting portion 252 of the ejecting member 25 is mounted on the recessed portion 23 of the receiving frame 20. The receiving frame 20 is mounted on the main body 11 of the housing 10. The entrance 211 of the receiving frame 20 faces the through hole 14. Then, the elastic members 42 are respectively fitted around the posts 415 of the protective cover 41. The two sliders 43 are positioned at opposite ends of the protective cover 41. The two opposite arms 414 of each pair of the protective cover 41 are engaged with one end of the connecting block 434 of each slider 43, and the posts 415 are slidably received in the guiding holes 435. Each elastic member 42 is positioned between the connecting block 434 and the protective cover 41. The hooks 416 are used for stopping one end of the connecting block 434. Accordingly, the two sliders 43 are slidably assembled to the protective cover 41. Then, the extending block 412 of the protective cover 41 is inserted into the slot 33 of the tray 30. The receiving hole 34 is aligned with the pin hole 417. The pin 36 is engaged in the receiving hole 34 and the pin hole 417 such as through friction fit or threaded engagement. After that, the protective cover 41 with the tray 30 is inserted inside of the housing 10 through the through hole 14. The tray 30 is slidably received in and retained by the flanges 22. Distal ends of the sliders 43 are pushed to be respectively received in the latching groove 15. Accordingly, the protective cover 41 is locked on the housing 10. At that time, the first end 312 of the tray 30 is slid to press into the V-shaped elastic bodies 251 of the ejecting member 25 so that the ejecting member 25 is resiliently deformed. Thus, the assembly process of the chip card holder 100 is finished.

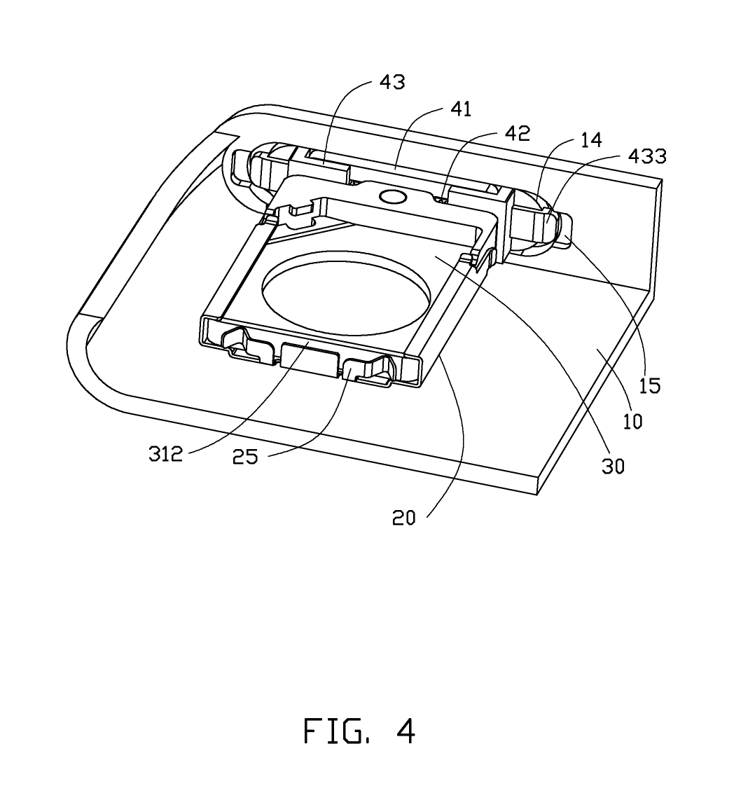

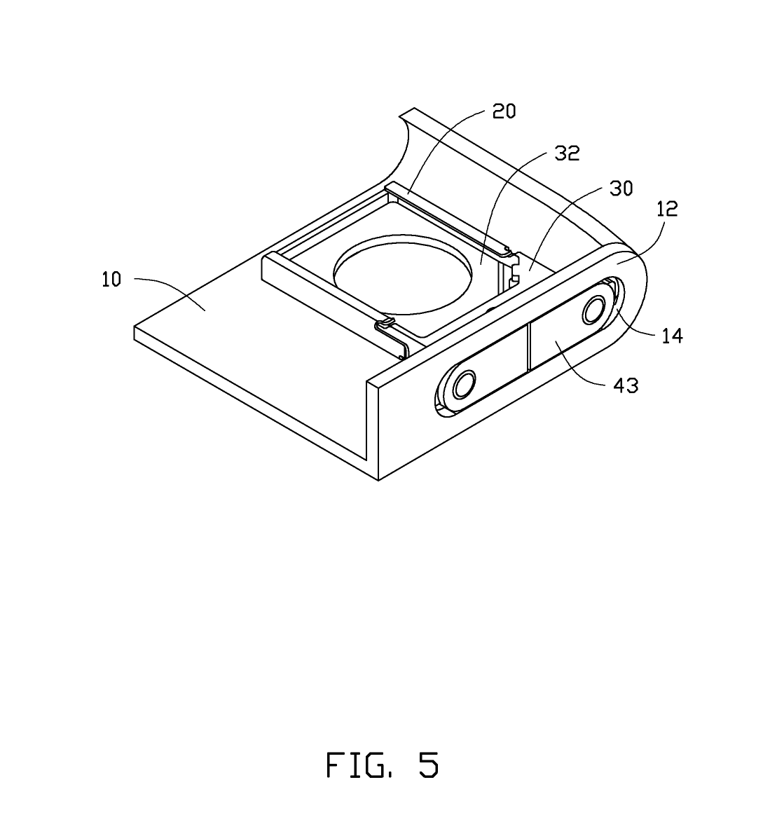

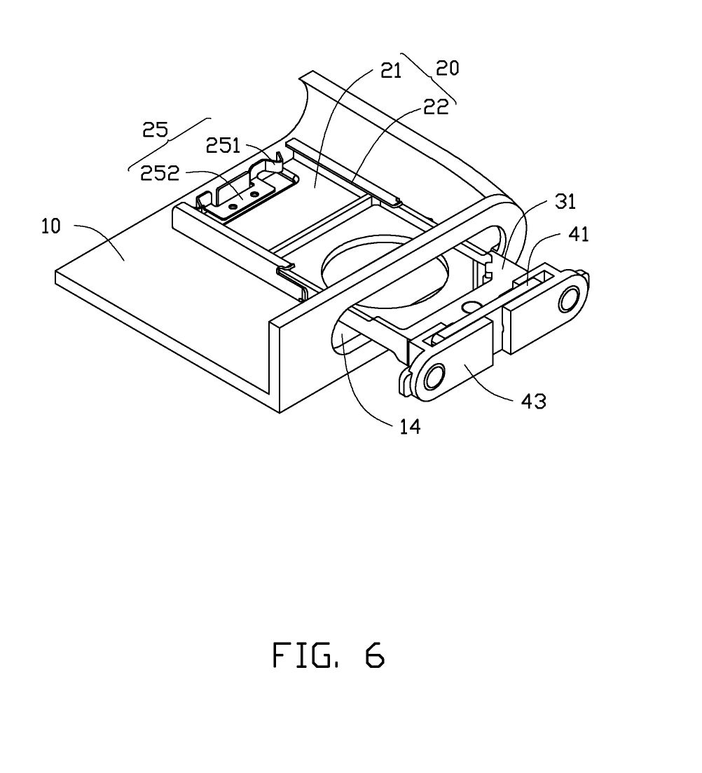

To remove the chip card, referring to FIGS. 4 to 6, the sliders 43 are slid relative to the protective cover 41 along the longitudinal axis of the through hole 14. The connecting blocks 434 slide toward the cover body 411 of the protective cover 41, and compress the elastic members 42 until the latching plates 433 are disengaged from the latching grooves 15 to unlock the protective cover 41 relative to the housing 10. The tray 30 is pushed out by the ejecting member 25 exerting a force on the tray 30 to move the protective cover 41 out of the through hole 14. The tray 30 is further pulled to extend from the hole 14. Accordingly, the tray 30 is slid out of the receiving frame 20. Thus, the chip card can then be easily removed from the tray 30.

As described above, the exemplary embodiment provides a chip card holder for portable electronic devices, such as mobile phones. The chip card holder can be easily opened, and the protective cover 41 with the sliders 43 can effectively protect the tray 30 and there is no visible hole to mar the appearance of the electronic devices.

Although numerous characteristics and advantages of the exemplary disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A chip card holder comprising:
a housing defining a through hole and two latching grooves;
a receiving frame mounted on the housing;
an ejecting member positioned at one end of the receiving frame;
a tray slidably received in the receiving frame and abutted by the ejecting member;
a protective cover mounted to the tray and received in the through hole; and
two sliders slidably positioned on the protective cover and releasably received in the latching grooves;
wherein the two sliders slide relative to the protective cover and are unlocked from the housing, the ejecting member ejects the tray from the housing.

2. The chip card holder of claim 1, wherein the receiving frame includes a frame body and two opposite flanges, thereby cooperatively defining a receiving cavity, an entrance is defined at one end of the frame body to allow the tray to be inserted into the receiving cavity therethrough.

3. The chip card holder of claim 1, wherein the ejecting member is made of elastic sheet, and includes two elastic bodies and a mounting portion, the mounting portion is located between the two elastic bodes, and is configured for being mounted on the receiving frame.

4. The chip card holder of claim 3, wherein the elastic body is substantially V-shaped configured for providing an elastic force for ejecting the tray from the receiving frame.

5. The chip card holder of claim 4, wherein the tray includes a first end and a second end, the first end abuts against the V-shaped elastic bodies, the second end defines a slot , the protective cover includes a cover body, an extending block extends from the cover body, and the extending block is received in the slot.

6. The chip card holder of claim 5, wherein the second end defines a receiving hole communicating with the slot, the extending block defines a pin hole, a pin is engageable in the receiving hole and the pin hole.

7. The chip card holder of claim 5, wherein the protective cover includes two pairs of opposite arms integrated with the cover body, each slider includes a first plate, a second plate, and a connecting block, the connecting block is positioned between the first plate and the second plate, the opposite arms of each pair of the protective cover are engaged with one end of the connecting block of each slider.

8. The chip card holder of claim 7, wherein the protective cover includes a latching plate, the latching plate is positioned at one end of the first plate, and is connected to the second plate, and the latching plate is received in each of the latching grooves.

9. The chip card holder of claim 8, further comprising two elastic members, wherein the protective cover includes two posts, each post is positioned between one pair of arms, each elastic member is fitted around one of the posts, and is positioned between the connecting block and the protective cover.

10. A portable electronic device, comprising:
a housing defining a through hole;
a receiving frame mounted on the housing;
an ejecting member positioned at one end of the receiving frame;
a tray slidably received in the receiving frame and abutted by the ejecting member;
a protective cover mounted on the tray;
a protective cover mounted to the tray and received in the through hole; and
two sliders slidably positioned on the protective cover;
wherein the two sliders slide relative to the protective cover and are unlocked from the housing, the ejecting member ejects the tray from the housing.

11. The portable electronic device of claim 10, wherein the protective cover includes two pairs of opposite arms integrated with the cover body, each slider includes a first plate, a second plate, and a connecting block, the connecting block is positioned between the first plate and the second plate, the opposite arms of each pair of the protective cover are engaged with one end of the connecting block of each slider.

12. The portable electronic device of claim 11, wherein the protective cover includes a latching plate, the latching plate is positioned at one end of the first plate, and is connected to the second plate, the housing defines a latching groove at opposite ends of the through hole, and the latching plate is received in each of the latching grooves.

13. The portable electronic device of claim 12, further comprising two elastic members, wherein the protective cover includes two posts, each post is positioned between one pair of arms, each elastic member is fitted around one of the posts, and is positioned between the connecting block and the protective cover.
